(19) United States
(12) Patent Application Publication
(10) Pub. No.: US 2009/0251193 A1
(43) Pub. Date: Oct. 8, 2009

(54) LEVEL SHIFTER AND CIRCUIT USING THE SAME

(75) Inventors: Shin-Tai Lo, Miaoli County (TW); Shao-Ping Hung, Hsinchu City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: RAYDIUM SEMICONDUCTOR CORPORATION, Hsinchu (TW)

(21) Appl. No.: 12/265,757

(22) Filed: Nov. 6, 2008

(30) Foreign Application Priority Data
Apr. 3, 2008 (TW) 97112337

(51) Int. Cl. H03L 5/00

(52) U.S. Cl. 327/333

(57) ABSTRACT

A level shifter consisting of first to fifth transistors is provided. First ends of the first and second transistors are coupled to a first supply voltage. Control ends of third and fourth transistors respectively receive first and second input signals. First ends of the third and fourth transistors are respectively coupled to control ends of the second and first transistors, and are respectively coupled to second ends of the first and second transistors. Second ends of the third and fourth transistors are coupled to a second supply voltage. The first ends of the third and fourth transistors respectively output first and second output signals. A first end and a control end of the fifth transistor are coupled to the control ends of one and the other of the first and second transistors. A second end of the fifth transistor is coupled to the second supply voltage.

This application claims the benefit of Taiwan application Serial No. 97112337, filed Apr. 3, 2008, the subject matter of which is incorporated herein by reference.

### BACKGROUND OF THE INVENTION

1. Field of the Invention

The invention relates in general to a level shifter and a circuit using the same, and more particularly to a level shifter with the low current consumption and the low complexity, and a circuit using the same.

2. Description of the Related Art

FIG. 1 (Prior Art) is a circuit diagram showing a conventional level shifter 100 with a front-stage inverter and a post-stage inverter. Referring to FIG. 1, the level shifter 100 includes two N-type metal-oxide semiconductor (NMOS) transistors 110 and 120, and two P-type metal-oxide semiconductor (PMOS) transistors 130 and 140. The level shifter 100 is driven by a supply voltage VH. The gates of the transistors 110 and 120 respectively receive input signals A and A′. The input signals A and A′ are respectively an input and an output of a front-stage inverter 150. In a normal state, the input signals A and A′ have inverse phases. The sources of the transistors 110 and 120 are grounded. The drains of the transistors 110 and 120 are respectively coupled to the drains of the transistors 130 and 140, respectively coupled to the gates of the transistors 140 and 130, and respectively output output signals B′ and B. In the normal state, the output signals B and B′ have inverse phases. The sources of the transistors 130 and 140 receive the supply voltage VH. The output signal B is outputted to a post-stage inverter 160, which is a complementary metal-oxide semiconductor (CMOS) inverter and includes a PMOS transistor 161 and an NMOS transistor 162. The post-stage inverter 160 generates an output signal x, which is an inverse of the output signal B.

The front-stage inverter 150 is driven by a supply voltage VL, which is lower than the supply voltage VH and is generated by a voltage generator according to the supply voltage VH. The supply voltage VH is generated before the supply voltage VL is generated. The level shifter 100 receives the input signals A and A′ with the lower levels, and outputs the output signals B and B′ with the higher levels.

However, the supply voltage VH has been generated in an initial state, and the input signals A and A′ are at the low levels when the supply voltage VL has not been generated. So, the transistors 110 and 120 are turned off, and the output signals B and B′ are pulled up to the intermediate levels (VH-Vthp) with the increase of the supply voltage VH, wherein Vthp is the threshold voltage of the transistors 130 and 140.

Thus, the output signal B at the intermediate level causes the two transistors 161 and 162 of the post-stage inverter 160 to turn on simultaneously so that high currents simultaneously flow through the transistors 161 and 162. Thus, the voltage source of the supply voltage VH has the high current consumption. More seriously, the supply voltage VH cannot be kept at the correct level so that the supply voltage VL also cannot be kept at the correct level.

On the other hand, when the supply voltages VH and VL are changed from the normal state to a power-saving state, the supply voltage VL stops supplying the electric power. At this time, the input signals A and A′ of the level shifter 100 are turned into the low levels so that the transistors 110 and 120 are turned off. At this time, the output signal, which is originally kept at the low level, is pulled up to the intermediate level. Thus, the post-stage inverter 160 has the malfunction, and the voltage source of the supply voltage VH has the high current consumption.

### SUMMARY OF THE INVENTION

The invention is directed to a level shifter, which can operate normally in an initial state, a normal state and a power-saving state and has the properties of the low circuit complexity and the low power consumption.

According to a first aspect of the present invention, a level shifter consisting of first to fifth transistors is provided. First ends of the first and second transistors are coupled to a first supply voltage. Control ends of the third and fourth transistors respectively receive a first input signal and a second input signal. A first end of the third transistor is coupled to a control end of the second transistor. A first end of the fourth transistor is coupled to a control end of the first transistor. The first ends of the third and fourth transistors are respectively coupled to second ends of the first and second transistors. Second ends of the third and fourth transistors are coupled to a second supply voltage. The first end of the third transistor is for outputting a first output signal. The first end of the fourth transistor is for outputting a second output signal. The fifth transistor has a first end coupled to the control end of one of the first and second transistors, a control end coupled to the control end of the other of the first and second transistors, and a second end coupled to the second supply voltage.

According to a second aspect of the present invention, a circuit consisting of a logic unit, a complementary metal-oxide semiconductor (CMOS) inverter, a level shifter and a voltage generator is provided. The logic unit generates a first input signal and a second input signal. The level shifter has an output end and includes first to fifth transistors. First ends of the first and second transistors are coupled to a first supply voltage. Control ends of the third and fourth transistors respectively receive the first input signal and the second input signal. A first end of the third transistor is coupled to a control end of the second transistor. A first end of the fourth transistor is coupled to a control end of the first transistor. The first ends of the third and fourth transistors are respectively coupled to second ends of the first and second transistors. Second ends of the third and fourth transistors are coupled to a second supply voltage. The first end of the third transistor is for outputting a first output signal. The first end of the fourth transistor is for outputting a second output signal to a second inverter. The first end of the fourth transistor or the first end of the third transistor serves as the output end. The fifth transistor has a first end coupled to the control end of one of the first and second transistors, a control end coupled to the control end of the other of the first and second transistors, and a second end coupled to the second supply voltage. The voltage generator receives the first supply voltage and generates a third supply voltage inputted to the logic unit. When the logic unit is driven by the third supply voltage, the first and second input signals have inverse phases, and a higher one of levels of the first input signal and the second input signal is substantially equal to the level of the third supply voltage. When the logic unit is not powered by the third supply voltage, the first and second input signals outputted by the logic unit have low levels. The output end of the level shifter is electrically connected to the CMOS inverter.

The invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a circuit diagram showing a conventional level shifter with a front-stage inverter and a post-stage inverter.

FIG. 2 is a circuit diagram showing a level shifter and its logic unit according to an embodiment of the invention.

FIG. 3 shows an example of waveforms of a supply voltage and output signals of FIG. 2 in an initial state.

FIG. 4 shows an example of waveforms of the supply voltage and the output signals of FIG. 2 in a power-saving state.

FIG. 5 shows another example of waveforms of the supply voltage and the output signals of FIG. 2 in the power-saving state.

FIG. 6 is a circuit diagram showing a level shifter and its logic unit according to another embodiment of the invention.

FIG. 7 (Prior Art) is a circuit diagram showing another conventional level shifter and its logic unit.

FIG. 8 (Prior Art) is a circuit diagram showing still another conventional level shifter and its logic unit.

FIG. 9 shows a circuit using the level shifter of this embodiment.

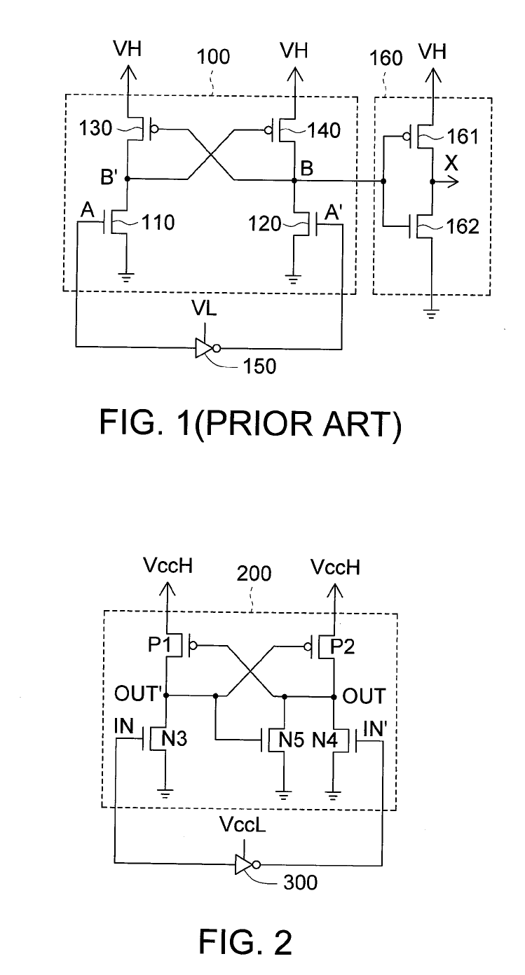

### DETAILED DESCRIPTION OF THE INVENTION

FIG. 2 is a circuit diagram showing a level shifter 200 and its logic unit according to an embodiment of the invention. Referring to FIG. 2, the level shifter 200 is consisted of transistors P1, P2, N3, N4 and N5. The first ends of the transistors P1 and P2 are coupled to a first supply voltage VccH.

The control ends of the transistors N3 and N4 respectively receive input signals IN and IN′. The first end of the transistor N3 is coupled to the control end of the transistor P2. The first end of the transistor N4 is coupled to the control end of the transistor P1. The first ends of the transistors N3 and N4 are respectively coupled to the second ends of the transistors P1 and P2. The second ends of the transistors N3 and N4 are coupled to a second supply voltage. In this embodiment, the second supply voltage is a ground voltage. The first end of the transistor N3 outputs an output signal OUT′. The first end of the transistor N4 outputs an output signal OUT.

The first end of the transistor N5 is coupled to the control end of the transistor P1, the control end of the transistor N5 is coupled to the control end of the transistor P2. The second end of the transistor N5 is coupled to the second supply voltage.

As for a metal-oxide semiconductor (MOS) transistor, the control end of the transistor is the gate, and the first and second ends of the transistor are respectively one and the other of the drain and the source.

In this embodiment, the input signals IN and IN′ are generated by a logic unit 300, which is an inverter, for example. When the logic unit 300 is driven by a supply voltage VccL, the input signals IN and IN′ outputted by the logic unit 300 have inverse phases. When the logic unit 300 is not powered by the supply voltage VccL, the input signals IN and IN′ outputted by the logic unit 300 have the low levels.

In this embodiment, the first supply voltage VccH has been initially generated while the supply voltage VccL has not been generated in an initial state so that the input signals IN and IN′ have the low levels. In a normal state, the first supply voltage VccH and the supply voltage VccL have been generated to respectively and normally drive the level shifter 200 and the logic unit 300. After the normal state is changed to a power-saving state, the first supply voltage VccH still continuously supplies the electric power. In the power-saving state, the supply voltage VccL stops supplying the electric power and the logic unit 300 is not powered by the supply voltage VccL so that the input signals IN and IN′ have the low levels.

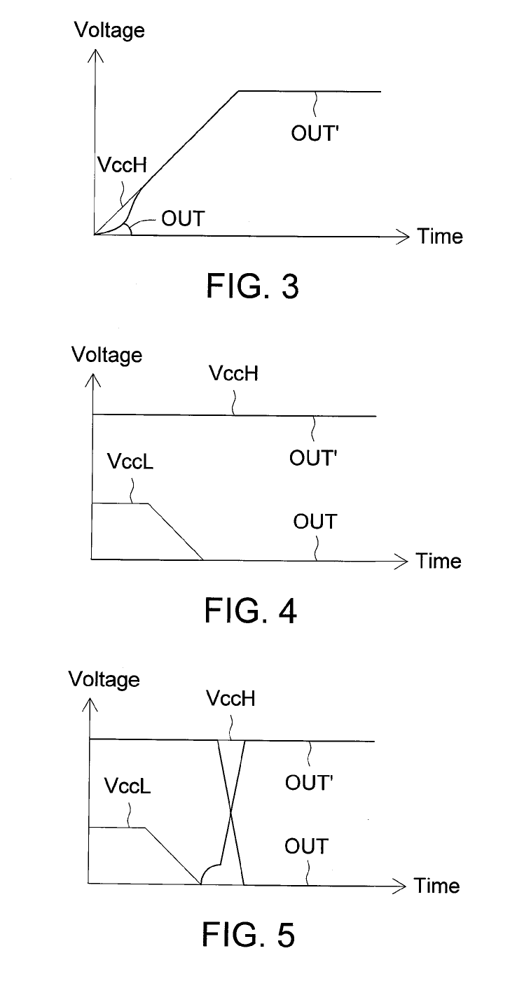

The operations of the level shifter according to this embodiment of the invention in the initial state, the normal state and the power-saving state will be respectively described in the following. FIG. 3 shows an example of waveforms of the supply voltage VccH and the output signals OUT and OUT′ of FIG. 2 in the initial state. As shown in FIGS. 2 and 3, the supply voltage VccL has not yet been generated in the initial state. Thus, the transistors N3 and N4 are turned off. The supply voltage VccH is increased with time. In the period when the supply voltage VccH is increased, the subthreshold currents of the transistors P1 and P2 increase the levels of the output signals OUT and OUT′.

When the levels of the output signals OUT and OUT′ are higher than the threshold voltage of the transistor N5, the transistor N5 is turned on. Thus, the level of the output signal OUT is pulled down to the ground voltage. Thus, the transistor P1 is turned on, and the level of the output signal OUT′ is pulled up to the level of the supply voltage VccH. Consequently, in the initial state when the supply voltage VccH has been generated and the supply voltage VccL has not been generated, the output signals OUT and OUT′ respectively have the low level and the high level.

Compared with the conventional level shifter, which generates the input signal with the intermediate level in the initial state, the level shifter 200 of this embodiment does not cause the post-stage logic unit, such as an inverter, to malfunction. In addition, the voltage source of the supply voltage VccH for the level shifter 200 of this embodiment does not generate high current consumption in the initial state during power-on period.

In the normal state, the supply voltages VccH and VccL respectively and normally drive the level shifter 200 and the logic unit 300. The logic unit 300 generates the input signals IN and IN′, which have inverse phases, to the level shifter 200. When the input signal IN has the high level (i.e., the level of the supply voltage VccL) and the input signal IN′ has the low level, the transistor N3 is turned on and the transistor N4 is turned off. Because the transistor N3 is turned on, the level of the output signal OUT′ is pulled down to the ground voltage. Thus, the transistor P2 is turned on and the transistor N5 is turned off. After the transistor P2 is turned on, the level of the output signal OUT is pulled up to the level of the supply voltage VccH.

Thus, when the input signal IN has the high level and the input signal IN′ has the low level, the level shifter 200 generates the output signal OUT′ with the low level, and the output signal OUT with the high level.

Oppositely, when the input signal IN has the low level and the input signal IN′ has the high level in the normal state, the level shifter 200 pulls up the level of the output signal OUT′ to the level of the supply voltage VccH, and the output signal OUT has the low level. In this case, the operations of the level shifter 200 are similar to those mentioned hereinabove, so detailed descriptions thereof will be omitted.

Because the level of the supply voltage VccL is lower than that of the supply voltage VccH, the level shifter of this embodiment receives the input signal with the lower level, and can output the output signal with the higher level.

FIG. 4 shows an example of waveforms of the supply voltage VccH and the output signals OUT and OUT′ of FIG. 2 in the power-saving state. As shown in FIGS. 2 and 4, the supply voltage VccH still normally drives the level shifter 200 in the power-saving state, and the supply voltage VccL stops supplying the electric power and does not drive the logic unit 300. In this example, before the supply voltage VccL stops supplying the electric power, it is assumed that the input signal IN has the low level, and the input signal IN′ has the high level. At this time, the output signal OUT has the low level, and the output signal OUT′ has the high level.

After the supply voltage VccL stops supplying the electric power, it is assumed that the input signal IN has the low level and the input signal IN′ is also decreased to the low level. Therefore, the transistors N3 and N4 are turned off. However, the transistor N5 is still turned on, the output signal OUT is pulled down to the low level so that the transistor P1 is turned on. Thus, the output signal OUT′ is pulled up to the level of the supply voltage VccH. Thus, the transistor N5 is still turned on, and the transistor P2 is turned off. Thus, the output signals OUT and OUT′ are respectively kept at the low level and the high level, as shown in FIG. 4.

Thus, before the state is changed to the power-saving state, the output signal OUT has the low level and the output signal OUT′ has the high level when the input signal IN has the low level and the input signal IN′ has the high level. After the state is changed to the power-saving state, the output signals OUT and OUT′ are still respectively kept at the low level and the high level, as shown in FIG. 4.

FIG. 5 shows another example of waveforms of the supply voltage VccH and the output signals OUT and OUT′ of FIG. 2 in the power-saving state. As shown in FIGS. 2 and 5 of this example, before the supply voltage VccL stops supplying the electric power, it is assumed that the input signal IN has the high level and the input signal IN′ has the low level. At this time, the output signal OUT has the high level, and the output signal OUT′ has the low level.

When the normal state is changed to the power-saving state, the input signal IN is decreased down to the low level. Thus, the transistor N3 is turned off. Because the output signal OUT has the high level, the transistor P1 is turned off. However, the subthreshold current of the transistors P1 and N3 generated according to the supply voltage VccH increases the level of the output signal OUT′. When the output signal OUT′ is pulled up and exceeds the threshold voltage of the transistor N5, the transistor N5 is turned on. Thus, the output signal OUT is pulled down to the low level so that the transistor P1 is turned on. Thus, the output signal OUT′ is pulled up to the high level.

Thus, before the state is changed to the power-saving state, the output signal OUT has the high level and the output signal OUT′ has the low level when the input signal IN has the high level and the input signal IN′ has the low level. After the state is changed to the power-saving state, the output signal OUT is pulled up to the high level, and the output signal OUT′ is pulled down to the low level, as shown in FIG. 5.

As mentioned hereinabove, it is obtained that when the output signals OUT and OUT′ have either the high levels or the low levels before the state is changed to the power-saving state, the output signal OUT always has the low level and the output signal OUT′ always has the high level after the state is changed to the power-saving state.

Compared with the conventional level shifter 100, in which the output signal, kept at the low level, in the output signals B and B′ is pulled up to the intermediate level when the normal state is changed to the power-saving state, the level shifter 200 of this embodiment can make the output signal have the high level or the low level instead of the intermediate level in the power-saving state. Such an output signal will not make the post-stage logic unit, such as the CMOS inverter, to malfunction, and also will not make the post-stage logic unit generate the abnormally high current consumption.

In this embodiment, the transistors P1 and P2 are preferably PMOS transistors, and the transistors N3 to N5 are preferably NMOS transistors.

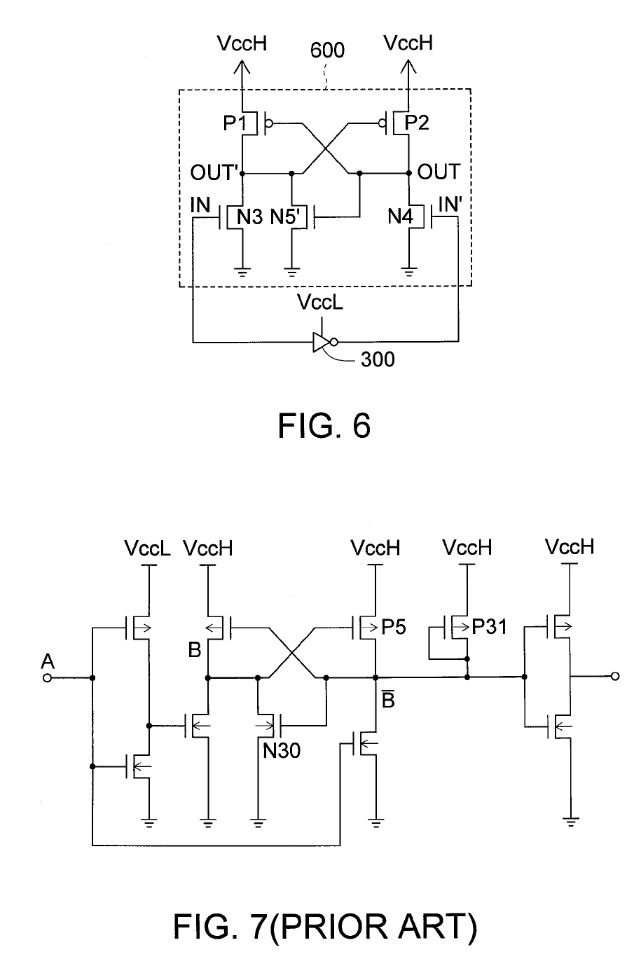

FIG. 6 is a circuit diagram showing a level shifter 600 and its logic unit according to another embodiment of the invention. As shown in FIG. 6, what is different from the level shifter 200 is that the connections of a transistor N5′ of the level shifter 600 are different from those of the transistor N5 of the level shifter 200. The first end of the transistor N5′ is coupled to the control end of the transistor P2. The control end of the transistor N5′ is coupled to the control end of the transistor P1. The second end of the transistor N5′ is coupled to the ground voltage. The operations of the level shifter 600 are similar to those of the level shifter 200, so detailed descriptions thereof will be omitted.

The level shifter of this embodiment will be compared with other conventional level shifters. FIG. 7 (Prior Art) is a circuit diagram showing another conventional level shifter and its logic unit, as disclosed in U.S. Pat. No. 6,781,413. The conventional level shifter of FIG. 7 includes a transistor P31 for pre-charging. The first end of the transistor P31 is coupled to the supply voltage VccH, the control end of the transistor P31 is coupled to the second end of the transistor P31, and the second end of the transistor P31 is coupled to the second end of the transistor P5.

When the conventional level shifter of FIG. 7 is in the initial state, the transistor P31 is turned on so that the level of the output signal B̅ is pulled up to the level of the supply voltage VccH. Consequently, the transistor N30 is turned on so that the output signal B is pulled down to the ground voltage. Thus, the drawbacks of the conventional level shifter 100 in the initial state may be improved.

In the conventional level shifter of FIG. 7, however, if the input signal A has the high level in normal operation state, the transistor P31 is still turned on so that the high current flows through the transistor P31 and the high power consumption is generated. Thus, compared with the conventional level shifter of FIG. 7, the level shifters 200 and 600 of the embodiments of the invention further have the power-saving effect. In addition, compared with the conventional level shifter of FIG. 7, in which six transistors are used, each of the level shifters 200 and 600 according to the embodiments of the invention only uses five transistors. Thus, the level shifter according to each embodiment of the invention has the lower circuit complexity and the lower manufacturing cost.

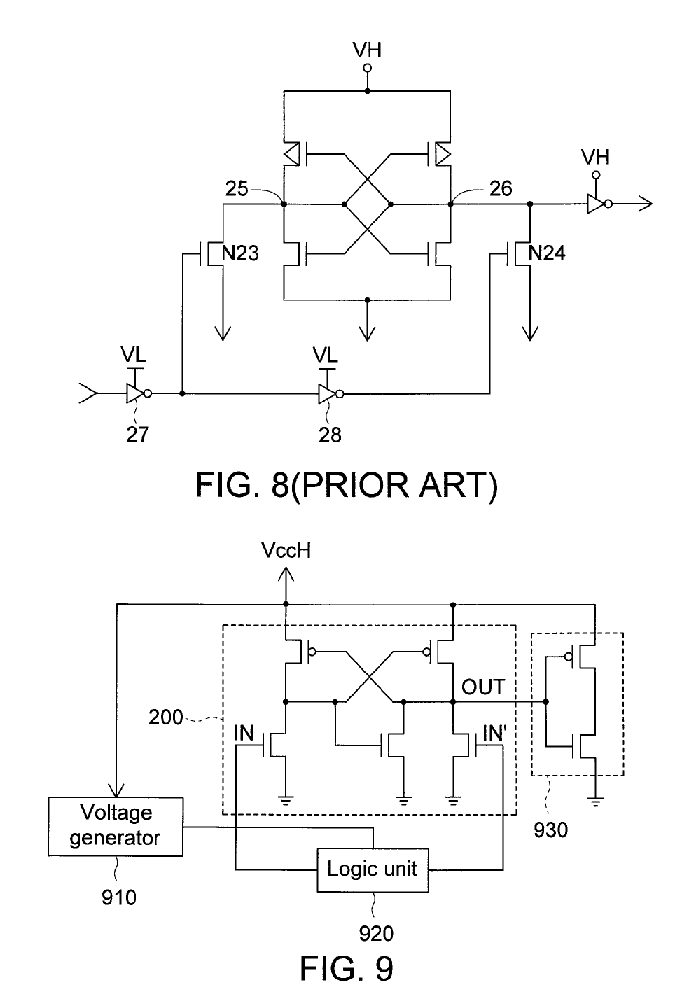

FIG. 8 (Prior Art) is a circuit diagram showing still another conventional level shifter and its logic unit, as disclosed in U.S. Pat. No. 6,809,544. Referring to FIG. 8, the control ends of the transistors N23 and N24 respectively receive the input signals transmitted by the logic unit 27 and the logic unit 28. Before the normal state is changed to the power-saving state, the output signal on the node 26 has the low level and the output signal on the node 25 has the high level if the input signal received by the transistor N23 has the low level and the input signal received by the transistor N24 has the high level. After the state is changed to the power-saving state, the output signals on the nodes 26 and 25 are still respectively kept at the low level and the high level. Oppositely, before the state is changed to the power-saving state, the output signal on the node 26 has the high level and the output signal on the node 25 has the low level if the input signal received by the transistor N23 has the high level and the input signal received by the transistor N24 has the low level. After the state is changed to the power-saving state, the output signals on the nodes 26 and 25 are still respectively kept on the high level and the low level.

Thus, in the power-saving state, the output signals on the nodes 25 and 26 of the conventional level shifter of FIG. 8 are kept at the levels before the power-saving state is entered. Therefore, the level of the output signal of the conventional level shifter of FIG. 8 is determined according to the level before the power-saving state is entered. In the power-saving state, if the post-stage logic unit has to receive a signal with a specific level to achieve the power-saving effect, the conventional level shifter of FIG. 8 must receive a specific input signal to generate the output signal with the specific level so that the post-stage logic unit can enter the power-saving state.

Compared with the prior art, when the input signals IN and IN′ received by the level shifters 200 and 600 have either the high levels or the low levels before the state is changed to the power-saving state in the two embodiments of the invention, the output signal OUT always has the low level, and the output signal OUT′ always has the high level after the state is changed to the power-saving state. Thus, when the power-saving mode is entered, the post-stage logic unit can directly enter the power-saving mode without the first provision of the input signals IN and IN′ having the specific levels. So, each of the level shifters 200 and 600 according to the two embodiments of the invention has the advantages that the operation is easy and the circuit design is easy.

In addition, compared with the conventional level shifters of FIGS. 7 and 8, in which six transistors are used, each of the level shifters 200 and 600 according to the embodiments of the invention only uses five transistors. Thus, the level shifter according to each embodiment of the invention has the lower circuit complexity and the lower manufacturing cost.

In addition, the level shifter 200 may be applied to the circuit of FIG. 9, for example. The circuit of FIG. 9 includes a voltage generator 910, a logic unit 920, the level shifter 200 and a CMOS inverter 930. The voltage generator 910 receives the supply voltage VccH and generates the supply voltage VccL, which is inputted to the logic unit 920.

The logic unit 920 generates the input signals IN and IN′ serving as the inputs of the level shifter 200. In this embodiment, the logic unit 920 is an inverter, for example. The output end OUT of the level shifter 200 is electrically connected to the CMOS inverter 930.

When the logic unit 920 is powered by the supply voltage VccL, the input signals IN and IN′ have inverse phases. The level of the input signal which is of the high level is substantially equal to the level of the supply voltage VccL. When the logic unit 920 is not powered by the supply voltage VccL, the input signals IN and IN′ outputted by the logic unit 920 have the low levels.

In the initial state, the voltage generator 910 has not outputted the supply voltage VccL to the logic unit 920. In the normal state, the voltage generator 910 normally outputs the supply voltage VccL to the logic unit 920. In the power-saving state, the voltage generator 910 stops outputting the supply voltage VccL to the logic unit 920.

Although the level shifter in the circuit of FIG. 9 is the level shifter 200, the level shifter 200 may be replaced with the level shifter 600.

Using the level shifter of each embodiment of the invention, the circuit of FIG. 9 can normally operate in the initial state, the normal state and the power-saving state, and is free from the high current consumption of the CMOS inverter 930 in the initial state and the power-saving state. Thus, the circuit of FIG. 9 has the advantages of the low current consumption and the low complexity.

While the invention has been described by way of examples and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A level shifter, consisting of:
a first transistor and a second transistor, wherein first ends of the first and second transistors are coupled to a first supply voltage;
a third transistor and a fourth transistor, wherein control ends of the third and fourth transistors respectively receive a first input signal and a second input signal, a first end of the third transistor is coupled to a control end of the second transistor, a first end of the fourth transistor is coupled to a control end of the first transistor, the first ends of the third and fourth transistors are respectively coupled to second ends of the first and second transistors, second ends of the third and fourth transistors are coupled to a second supply voltage, the first end of the third transistor is for outputting a first output signal, and the first end of the fourth transistor is for outputting a second output signal; and
a fifth transistor having a first end coupled to the control end of one of the first and second transistors, a control end coupled to the control end of the other of the first and second transistors, and a second end coupled to the second supply voltage.

2. The level shifter according to claim 1, wherein the first input signal and the second input signal are generated by a logic unit, the first and second input signals outputted by the logic unit have inverse phases when the logic unit is driven by a third supply voltage, and the first and second input signals outputted by the logic unit have low levels when the logic unit is not powered by the third supply voltage.

3. The level shifter according to claim 2, wherein the first supply voltage and the third supply voltage have different levels.

4. The level shifter according to claim 3, wherein the first supply voltage is higher than the third supply voltage.

5. The level shifter according to claim 1, wherein the first end of the fifth transistor is coupled to the control end of the first transistor, and the control end of the fifth transistor is coupled to the control end of the second transistor.

6. The level shifter according to claim 1, wherein the first end of the fifth transistor is coupled to the control end of the second transistor, and the control end of the fifth transistor is coupled to the control end of the first transistor.

7. The level shifter according to claim 1, wherein the second supply voltage is a ground voltage.

8. The level shifter according to claim 1, wherein each of the first and second transistors is a P-type metal-oxide semiconductor (PMOS), and each of the third to fifth transistors is an N-type metal-oxide semiconductor (NMOS).

9. A circuit, consisting of:
a logic unit for generating a first input signal and a second input signal;
a complementary metal-oxide semiconductor (CMOS) inverter;
a level shifter having an output end, the level shifter comprising:
a first transistor and a second transistor, wherein first ends of the first and second transistors are coupled to a first supply voltage;
a third transistor and a fourth transistor, wherein control ends of the third and fourth transistors respectively receive the first input signal and the second input signal, a first end of the third transistor is coupled to a control end of the second transistor, a first end of the fourth transistor is coupled to a control end of the first transistor, the first ends of the third and fourth transistors are respectively coupled to second ends of the first and second transistors, second ends of the third and fourth transistors are coupled to a second supply voltage, the first end of the third transistor is for outputting a first output signal, the first end of the fourth transistor is for outputting a second output signal to a second inverter, and the first end of the fourth transistor or the first end of the third transistor serves as the output end; and
a fifth transistor having a first end coupled to the control end of one of the first and second transistors, a control end coupled to the control end of the other of the first and second transistors, and a second end coupled to the second supply voltage; and
a voltage generator for receiving the first supply voltage and generating a third supply voltage inputted to the logic unit, wherein:
when the logic unit is powered by the third supply voltage, the first and second input signals have inverse phases, and a higher one of levels of the first input signal and the second input signal is substantially equal to the level of the third supply voltage;
when the logic unit is not powered by the third supply voltage, the first and second input signals outputted by the logic unit have low levels; and
the output end of the level shifter is electrically connected to the CMOS inverter.

10. The circuit according to claim 9, wherein the first supply voltage and the third supply voltage have different levels.

11. The circuit according to claim 10, wherein the first supply voltage is higher than the third supply voltage.

12. The circuit according to claim 9, wherein the first end of the fifth transistor is coupled to the control end of the first transistor, and the control end of the fifth transistor is coupled to the control end of the second transistor.

13. The circuit according to claim 9, wherein the first end of the fifth transistor is coupled to the control end of the second transistor, and the control end of the fifth transistor is coupled to the control end of the first transistor.

14. The circuit according to claim 9, wherein the second supply voltage is a ground voltage.

15. The circuit according to claim 9, wherein each of the first and second transistors is a P-type metal-oxide semiconductor (PMOS), and each of the third to fifth transistors is an N-type metal-oxide semiconductor (NMOS).
